(19) United States
(12) Patent Application Publication
(10) Pub. No.: US 2026/0286182 A1
(43) Pub. Date: Sep. 24, 2026

(54) POLISHING COMPOSITION, AND POLISHING METHOD

(71) Applicant: FUJIMI INCORPORATED, Kiyosu-shi (JP)

(72) Inventors: Masaki Tada, Kiyosu-shi (JP); Noriyuki Tanaka, Kiyosu-shi (JP); Akane Kumayama, Kiyosu-shi (JP); Daichi Jimbo, Kiyosu-shi (JP)

(73) Assignee: FUJIMI INCORPORATED, Kiyosu-shi (JP)

(21) Appl. No.: 19/546,558

(22) Filed: Feb. 23, 2026

(30) Foreign Application Priority Data
Mar. 19, 2025 (JP) 2025-044381

(51) Int. Cl. C09G 1/02; A01N 25/02; A01N 43/10; A01P 1/00; B24B 37/04; H10P 52/40

(52) U.S. Cl. CPC C09G 1/02; A01N 25/02; A01N 43/10; A01P 1/00; B24B 37/044; H10P 52/402; H10P 52/403; H10P 52/407

(57) ABSTRACT

The present disclosure provides a polishing composition having excellent storage stability that shows little change in polishing removal rate even after long-term storage, can stably maintain polishing performance, and can suppress proliferation of viable bacteria. The present disclosure is a polishing composition contains: (A) abrasive grains; (B) a biocide; (C) a polishing removal rate improver for a material having a silicon-silicon bond; and (D) a polyoxyalkylene compound, wherein the component (B) is at least one selected from the group consisting of an isothiazolinone compound and a thiazolinone compound, and wherein the component (C) is a water-soluble polymer other than the component (D).

### CROSS-REFERENCE TO RELATED APPLICATION

The entire disclosure of Japanese Patent Application No. 2025-044381 filed on Mar. 19, 2025, is incorporated herein by reference in its entirety.

### BACKGROUND

### 1. Technical Field

The present disclosure relates to a polishing composition, and a polishing method.

### 2. Description of Related Arts

In recent years, as the multi level interconnection of semiconductor substrate surfaces has progressed, a so-called chemical mechanical polishing (CMP) technology has been utilized, which physically polishes and flattens semiconductor substrates when producing devices. The CMP is a method for flattening the surface of an object to be polished (polishing object) such as a semiconductor substrate using a polishing composition (slurry) that contains abrasive grains such as silica, alumina or ceria, an anti-corrosion agent, a surfactant, or the like. The object to be polished (polishing object) is silicon, polysilicon, silicon oxide film (silicon oxide), silicon nitride, a wiring or plug composed of metal, or the like.

Such a polishing composition may suffer from progression of proliferation of viable bacteria, resulting in deterioration of storage stability. From the viewpoint of ensuring this storage stability, for example, Japanese Patent Laid-Open No. 2007-88379 (corresponding to U.S. Patent Application Publication No. 2007/069176) proposes a polishing composition characterized by containing (a) colloidal silica whose surface is partially covered with aluminum atoms and (b) at least one or more types of compounds having an isothiazolin-3-one skeleton.

### SUMMARY

However, it has been found that, when polishing an object to be polished is performed after the polishing composition described in Japanese Patent Laid-Open No. 2007-88379 (corresponding to U.S. Patent Application Publication No. 2007/069176) is stored for a long period of time, a phenomenon occurs in which the polishing performance of the polishing composition changes as compared with that before storage.

Accordingly, an object of the present disclosure is to provide a polishing composition having excellent storage stability that shows little change in polishing removal rate even after long-term storage, can stably maintain polishing performance, and can suppress proliferation of viable bacteria.

In order to solve the above-described problem, the inventors of the present disclosure have conducted extensive studies. As a result, they have found that the above-described problem can be solved by a polishing composition containing: (A) abrasive grains; (B) a biocide; (C) a polishing removal rate improver for a material having a silicon-silicon bond; and (D) a polyoxyalkylene compound, wherein the component (B) is at least one selected from the group consisting of an isothiazolinone compound and a thiazolinone compound, and wherein the component (C) is a water-soluble polymer other than the component (D), leading to the completion of the aspect(s) of the present disclosure.

### DESCRIPTION OF EMBODIMENTS

The present disclosure is a polishing composition containing: (A) abrasive grains; (B) a biocide; (C) a polishing removal rate improver for a material having a silicon-silicon bond; and (D) a polyoxyalkylene compound, wherein the component (B) is at least one selected from the group consisting of an isothiazolinone compound and a thiazolinone compound, and wherein the component (C) is a water-soluble polymer other than the component (D). The polishing composition according to the present disclosure having such a configuration has excellent storage stability, showing little change in polishing removal rate even after long-term storage, being capable of stably maintaining polishing performance, and being capable of suppressing proliferation of viable bacteria.

Although the details of the reason why the above effect can be obtained by the polishing composition of the present disclosure are not clear, the reason is thought to be the mechanism as follows. Note that the mechanism is based on speculation, and the technical scope of the present disclosure is not restricted in any way by the mechanism.

Isothiazolinone compounds and thiazolinone compounds have a function of suppressing proliferation of viable bacteria, and also have a function of embrittling chemical bonds (for example, a silicon-silicon bond) of a material contained in an object to be polished to improve a polishing removal rate for the object to be polished. However, the inventors of the present disclosure have found that isothiazolinone compounds and thiazolinone compounds undergo alteration over time or alteration under acidic conditions, whereby the function of improving the polishing removal rate changes, resulting in a phenomenon in which polishing performance of a polishing composition changes before storage and after storage.

In view of such a technical problem, the inventors of the present disclosure have conducted extensive studies. As a result, they have found that the technical problem can be solved by a polishing composition containing, together with an isothiazolinone compound or a thiazolinone compound, a water-soluble polymer serving as a polishing removal rate improver for a material having a silicon-silicon bond, and a polyoxyalkylene compound. It is considered that the water-soluble polymer serving as a polishing removal rate improver for a material having a silicon-silicon bond and the polyoxyalkylene compound form a protective film on a surface of an object to be polished, and have a function of suppressing action of the isothiazolinone compound or the thiazolinone compound on the object to be polished. As a result of this, it is considered that action of the isothiazolinone compound or the thiazolinone compound on the object to be polished is suppressed, and even if the isothiazolinone compound or the thiazolinone compound is altered due to long-term storage, a change in polishing performance of the polishing composition is suppressed, so that original polishing performance can be stably maintained. In addition, it is considered that the polishing composition according to the present disclosure containing an isothiazolinone compound or a thiazolinone compound suppresses proliferation of viable bacteria, and together with the above-described stabilization of polishing performance, has excellent storage stability.

Embodiments of the present disclosure will be described below. Note that the present disclosure is not limited to only the following embodiments.

In the present specification, unless otherwise specified, operations and measurements of physical properties or other factors are carried out under conditions of room temperature (20° C. or higher and 25° C. or lower)/relative humidity of 40% RH or more and 50% RH or less.

In the present specification, the expression “X or more and Y or less” is used in the sense that it includes the numerical values specified before and after it (X and Y) as the lower limit value and the upper limit value. In the case where “X or more and Y or less” is listed more than once, for example, if “X1 or more and Y1 or less, or X2 or more and Y2 or less” is described, the disclosure of each numerical value as the upper limit, the disclosure of each numerical value as the lower limit, and the combination of those upper and lower limits are all disclosed (that is, they constitute a valid basis for amendment). Specifically, amendment to X1 or more, amendment to Y2 or less, amendment to X1 or less, amendment to Y2 or more, amendment to X1 or more and X2 or less, amendment to X1 or more and Y2 or less, and others must all be considered lawful.

In addition, all combinations of the embodiments and descriptions disclosed in the present specification must be understood to be disclosed in the present application. That is, they must be understood as potentially serving as a basis for amendment.

Throughout the description, unless particularly stated otherwise, any expression in a singular form should be understood to encompass the concept of its plural form. Therefore, unless particularly stated otherwise, the article specifying a single form (for example, “a”, “an”, “the”, and the like in the case of English language) should be understood to encompass the concept of its plural form. Further, unless particularly stated otherwise, any term used in the present description should be understood as a term that is used to have the meaning conventionally used in the relevant technical field. Therefore, unless defined otherwise, all the technical terms and scientific terms used in the present description have the same meaning as generally understood by a person ordinarily skilled in the art to which the present invention is pertained. If there is any conflict in meaning, the present description (including the definitions) takes priority.

### [(A) Abrasive Grains]

The polishing composition according to the present disclosure contains (A) abrasive grains (an abrasive, hereinafter, also simply referred to as “component (A)”). The abrasive grains have the action of mechanically polishing an object to be polished, and improve the polishing removal rate for the object to be polished by the polishing composition.

There is no particular restriction on the type of the abrasive grains, and examples thereof include metal oxides such as silica, alumina, zirconia, and titania. As the abrasive grains, one type alone may be used or a combination of two or more types may be used. Commercial products of the abrasive grains may be used and synthetic products thereof may also be used.

The type of the abrasive grains is preferably silica, and more preferably colloidal silica. Examples of the method for producing colloidal silica include the sodium silicate method and the sol-gel method, and colloidal silica produced by any production method can be suitably used as the abrasive grains of the present disclosure. However, from the viewpoint of reducing metallic impurities, colloidal silica produced by the sol-gel method, which can be produced with high purity, is preferable.

Production of colloidal silica by the sol-gel method can be carried out using a conventionally known method. Specifically, colloidal silica can be obtained by using a hydrolyzable silicon compound (for example, alkoxysilane or derivative thereof) as a raw material, and subjecting it to a hydrolysis and condensation reaction.

In some embodiments of the present disclosure, the abrasive grains contained in the polishing composition are preferably anion-modified silica, and more preferably anion-modified colloidal silica. The abrasive grains are more preferably colloidal silica having an organic acid immobilized on the surface thereof. Colloidal silica having an organic acid immobilized on the surface thereof tends to have a larger absolute value of zeta potential in the polishing composition compared to normal colloidal silica having no organic acid immobilized.

Preferable examples of the colloidal silica having an organic acid immobilized on the surface thereof include colloidal silica having an organic acid group such as carboxylic acid group, sulfonic acid group, phosphonic acid group, or aluminic acid group immobilized on the surface thereof. Among these, from the viewpoint of easy production, colloidal silica having sulfonic acid or carboxylic acid immobilized on the surface thereof is preferable, and colloidal silica having sulfonic acid immobilized on the surface thereof (also referred to as sulfonic acid-modified colloidal silica) is more preferable.

Immobilization of an organic acid on the surface of colloidal silica is not accomplished by simply allowing the colloidal silica and the organic acid to coexist. For example, immobilization of sulfonic acid, which is one type of organic acid, on colloidal silica can be carried out by, for example, the method described in “Sulfonic acid-functionalized silica through quantitative oxidation of thiol groups”, Chem. Commun. 246-247 (2003). Specifically, colloidal silica having sulfonic acid immobilized on the surface thereof (also referred to as sulfonic acid-modified colloidal silica) can be obtained by coupling a silane coupling agent having a thiol group such as 3-mercaptopropyltrimethoxysilane to colloidal silica, followed by oxidation of the thiol group with hydrogen peroxide.

Alternatively, immobilization of carboxylic acid, which is one type of organic acid, on colloidal silica can be carried out by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, colloidal silica having carboxylic acid immobilized on the surface thereof (also referred to as carboxylic acid-modified colloidal silica) can be obtained by coupling a silane coupling agent containing a photoreactive 2-nitrobenzyl ester to colloidal silica, followed by photoirradiation.

There is no particular restriction on the shape of the abrasive grains, and it may be spherical or may be non-spherical. Specific examples of the non-spherical shape include, but are not particularly restricted to, various shapes such as a polygonal columnar shape such as a triangle pole and a square pole, a cylindrical shape, a straw bag shape in which the center part of the cylinder is swollen more than the end parts, a donut shape in which the center part of the disk is hollow, a plate shape, a so-called cocoon type shape having a constriction at the center part, a so-called associated type spherical shape in which a plurality of particles are integrated, a so-called kompeito shape having a plurality of protrusions on the surface, and a rugby ball shape.

There is no particular restriction on the size of the abrasive grains. For example, the average primary particle size (diameter) of the abrasive grains is preferably 5 nm or more, more preferably 8 nm or more, still more preferably 10 nm or more, and particularly preferably 12 nm or more. As the average primary particle size of the abrasive grains increases, the polishing removal rate for an object to be polished by the polishing composition is improved. Also, the average primary particle size of the abrasive grains is preferably 100 nm or less, more preferably 80 nm or less, still more preferably 60 nm or less, and particularly preferably 50 nm or less. As the average primary particle size of the abrasive grains decreases, it becomes easier to obtain a surface with fewer defects by polishing using the polishing composition. That is, the average primary particle size of the abrasive grains is preferably 5 nm or more and 100 nm or less, more preferably 8 nm or more and 80 nm or less, still more preferably 10 nm or more and 60 nm or less, and particularly preferably 12 nm or more and 50 nm or less. Note that the average primary particle size of the abrasive grains can be calculated on the basis of the specific surface area (SA) of the abrasive grains, as calculated by the BET method, assuming that the shape of the abrasive grains is a true sphere, for example. In the present specification, as the average primary particle size of the abrasive grains, the value measured by the method described in Examples is employed.

Also, the average secondary particle size (diameter) of the abrasive grains is preferably 10 nm or more, more preferably 15 nm or more, still more preferably 20 nm or more, and particularly preferably 25 nm or more. As the average secondary particle size of the abrasive grains increases, the resistance during polishing becomes smaller and polishing can be performed stably. Also, the average secondary particle size of the abrasive grains is preferably 400 nm or less, more preferably 300 nm or less, still more preferably 200 nm or less, and particularly preferably 100 nm or less. As the average secondary particle size of the abrasive grains decreases, the surface area per unit mass of the abrasive grains increases, which improves the frequency of contact with an object to be polished and further improves the polishing removal rate. That is, the average secondary particle size of the abrasive grains is preferably 10 nm or more and 400 nm or less, more preferably 15 nm or more and 300 nm or less, still more preferably 20 nm or more and 200 nm or less, and particularly preferably 25 nm or more and 100 nm or less. In the present specification, as the average secondary particle size of the abrasive grains, the value measured by the method described in Examples is employed.

The average degree of association of the abrasive grains is preferably 5.0 or less, more preferably 4.0 or less, still more preferably 3.0 or less, and particularly preferably 2.5 or less. As the average degree of association of the abrasive grains decreases, defects can be further reduced. Also, the average degree of association of the abrasive grains is preferably 1.0 or more, more preferably 1.5 or more, and still more preferably 2.0 or more. This average degree of association can be obtained by dividing the value of the average secondary particle size of the abrasive grains by the value of the average primary particle size. As the average degree of association of the abrasive grains increases, there is an advantageous effect that the polishing removal rate for an object to be polished by the polishing composition is improved.

Although there is no particular restriction on the upper limit of the aspect ratio of the abrasive grains in the polishing composition, it is preferably less than 2.0, more preferably 1.8 or less, and still more preferably 1.5 or less. Such a range can further reduce defects on the surface of an object to be polished. Note that the aspect ratio is the average of values obtained by defining the smallest circumscribed rectangles of images of abrasive grain particles by scanning electron microscopy and dividing the length of the long side of those rectangles by the length of the short side of the same rectangles, and can be determined using common image analysis software. Although there is no particular restriction on the lower limit of the aspect ratio of the abrasive grains in the polishing composition, it is preferably 1.0 or more, and more preferably 1.2 or more.

Although there is no particular restriction on the lower limit of D90/D10, which is the ratio of the diameter of particles where the cumulative particle mass from the finer particle side reaches 90% of the entire particle mass (D90) to the diameter of particles where the cumulative particle mass reaches 10% of the entire particle mass of the entire particles (D10), in the particle size distribution of the abrasive grains determined by the laser diffraction scattering method, it is preferably 1.1 or more, more preferably 1.4 or more, still more preferably 1.7 or more, and most preferably 2.0 or more. In addition, although there is no particular restriction on the upper limit of D90/D10, which is the ratio of the diameter of particles where the cumulative particle mass from the finer particle side reaches 90% of the entire particle mass (D90) to the diameter of particles where the cumulative particle mass reaches 10% of the entire particle mass of the entire particles (D10), in the particle size distribution of the abrasive grains in the polishing composition determined by the laser diffraction scattering method, it is preferably 3.0 or less, and more preferably 2.5 or less. Such a range can further reduce defects on the surface of an object to be polished.

The sizes of the abrasive grains (such as average primary particle size (diameter), average secondary particle size (diameter), aspect ratio, and D90/D10) can be appropriately controlled by selection and the like of a method for producing the abrasive grains.

Although there is no particular restriction on a concentration (content) of the abrasive grains in the polishing composition, it is preferably 0.5% by mass or more, more preferably 0.8% by mass or more, still more preferably 1% by mass or more, even more preferably more than 1% by mass, and particularly preferably 1.5% by mass or more with respect to 100% by mass of the total mass of the polishing composition. In addition, although there is no particular restriction on the concentration (content) of the abrasive grains, it is preferably 20% by mass or less, more preferably 15% by mass or less, still more preferably 10% by mass or less, and particularly preferably 8% by mass or less with respect to 100% by mass of the total mass of the polishing composition.

That is, the concentration (content) of the abrasive grains is preferably 0.5% by mass or more and 20% by mass or less, more preferably 0.8% by mass or more and 20% by mass or less, still more preferably 1% by mass or more and 15% by mass or less, even more preferably more than 1% by mass and 10% by mass or less, and particularly preferably 1.5% by mass or more and 8% by mass or less with respect to 100% by mass of the total mass of the polishing composition. Such a range can improve the polishing removal rate while keeping costs down. Note that, in the case where the polishing composition contains two or more types of abrasive grains, the concentration (content) of the abrasive grains means their total amount.

Although there is no particular restriction on zeta potential of the abrasive grains in the polishing composition of the present disclosure, it is preferably-5 mV or less. Here, “zeta (5) potential” is the potential difference that occurs at the interface between a solid and a liquid in contact with each other when they are in relative motion.

In the present disclosure, the zeta potential of the abrasive grains is preferably-60 mV or more and −10 mV or less, more preferably −50 mV or more and −13 mV or less, and still more preferably −40 mV or more and −15 mV or less. When the abrasive grains have a zeta potential in such a range, the polishing removal rate for an object to be polished can be further improved. Here, the zeta potential of the abrasive grains in the polishing composition is the value measured by the method described in Examples. The zeta potential of the abrasive grains can be adjusted by the amount of anionic groups (in particular, organic acid groups) possessed by the abrasive grains, pH of the polishing composition, and other factors.

### [(B) Biocide]

The polishing composition according to the present disclosure contains (B) a biocide (hereinafter, also simply referred to as “component (B)”). As described above, the component (B) has a function of suppressing proliferation of viable bacteria, and also has a function of embrittling chemical bonds (for example, a silicon-silicon bond) of a material contained in an object to be polished to improve a polishing removal rate for the object to be polished. The component (B) is at least one selected from the group consisting of an isothiazolinone compound and a thiazolinone compound. Commercial products of the component (B) may be used and synthetic products thereof may also be used.

Specific examples of the isothiazolinone compound include 2-methyl-4-isothiazolin-3-one (MIT), 5-chloro-2-methyl-4-isothiazolin-3-one (CMIT), 2-octyl-4-isothiazolin-3-one (OIT), 4,5-dichloro-2-n-octyl-4-isothiazolin-3-one (DCOIT), and 1,2-benzisothiazolin-3 (2H)-one (BIT).

Specific examples of the thiazolinone compound include 4,5-dichlorodithiazolinone, 4,5-benzodithiazolinone, and 4,5-trimethylenedithiazolinone.

Among these components (B), 1,2-benzisothiazolin-3 (2H)-one (BIT) is preferable.

Although there is no particular restriction on a concentration (content) of the component (B) in the polishing composition, it is preferably 1 ppm by mass (0.0001% by mass) or more, more preferably 5 ppm by mass (0.0005% by mass) or more, still more preferably 10 ppm by mass (0.001% by mass) or more, even more preferably 50 ppm by mass (0.005% by mass) or more, and particularly preferably 100 ppm by mass (0.01% by mass) or more with respect to 100% by mass of the total mass of the polishing composition. In addition, although there is no particular restriction on the concentration (content) of the component (B) in the polishing composition, it is preferably 10,000 ppm by mass (1% by mass) or less, more preferably 5,000 ppm by mass (0.5% by mass) or less, still more preferably 3,000 ppm by mass (0.3% by mass) or less, even more preferably 1,000 ppm by mass (0.1% by mass) or less, even more preferably 500 ppm by mass (0.05% by mass) or less, and particularly preferably 300 ppm by mass (0.03% by mass) or less with respect to 100% by mass of the total mass of the polishing composition.

That is, the concentration (content) of the component (B) in the polishing composition may be 1 ppm by mass (0.0001% by mass) or more and 10,000 ppm by mass (1% by mass) or less, 5 ppm by mass (0.0005% by mass) or more and 5,000 ppm by mass (0.5% by mass) or less, 10 ppm by mass (0.001% by mass) or more and 3,000 ppm by mass (0.3% by mass) or less, 50 ppm by mass (0.005% by mass) or more and 1,000 ppm by mass (0.1% by mass) or less, 50 ppm by mass (0.005% by mass) or more and 500 ppm by mass (0.05% by mass) or less, 50 ppm by mass (0.005% by mass) or more and 300 ppm by mass (0.03% by mass) or less, or 100 ppm by mass (0.01% by mass) or more and 300 ppm by mass (0.03% by mass) or less with respect to 100% by mass of the total mass of the polishing composition. Note that, in the case where the polishing composition contains two or more types of components (B), the concentration (content) of the component (B) is intended to be the total amount thereof.

### [(C) Polishing Removal Rate Improver for Material Having Silicon-Silicon Bond]

The polishing composition according to the present disclosure contains (C) a polishing removal rate improver for a material having a silicon-silicon bond (hereinafter, also simply referred to as “component (C)”). The component (C) has a function of improving a polishing removal rate for a material having a silicon-silicon bond. Also, it is considered that the component (C) forms a protective film on a surface of an object to be polished, and has a function of suppressing action of the isothiazolinone compound or the thiazolinone compound on the object to be polished.

The component (C) may be used alone as one type, or may be used in combination of two or more types. In addition, commercial products of the component (C) may be used and synthetic products thereof may also be used.

The component (C) is a water-soluble polymer other than (D) a polyoxyalkylene compound (hereinafter, also simply referred to as “component (D)”) described later. There is no particular restriction on the type of the water-soluble polymer, and any of a cationic water-soluble polymer, an anionic water-soluble polymer, a nonionic water-soluble polymer other than the component (D), and an amphoteric water-soluble polymer can be used. Among these, the component (C) is preferably at least one selected from the group consisting of an anionic water-soluble polymer and a nonionic water-soluble polymer other than the component (D). Furthermore, the component (C) is more preferably at least one selected from the group consisting of polycarboxylic acid, polycarboxylic acid amide, polycarboxylic acid ester, polycarboxylic acid salt, polysulfonic acid, polyphosphonic acid, and vinyl-based polymer.

Specific examples of the polycarboxylic acid include polyaspartic acid, polyglutamic acid, polymalic acid, polyacrylic acid, polymethacrylic acid, polymaleic acid, polyitaconic acid, polyfumaric acid, and poly(p-styrene carboxylic acid), as well as polyamide acid, an ammonium salt of polyamide acid, and a sodium salt of polyamide acid.

Specific examples of the polycarboxylic acid amide include polyacrylamide, polymethacrylamide, amino polyacrylamide, and amino polymethacrylamide.

Specific examples of the polycarboxylic acid ester include poly(methyl acrylate), poly(methyl methacrylate), poly(ethyl acrylate), and poly(ethyl methacrylate).

Specific examples of the polycarboxylic acid salt include an ammonium salt of polyacrylic acid, an ammonium salt of polymethacrylic acid, a sodium salt of polyacrylic acid, and a sodium salt of polymethacrylic acid.

Specific examples of the polysulfonic acid include polystyrene sulfonic acid, polyisoprene sulfonic acid, sulfonic acid (salt) group-containing polyvinyl alcohol (sulfonic acid-modified polyvinyl alcohol), sulfonic acid (salt) group-containing polyvinyl acetate (sulfonic acid-modified polyvinyl acetate), sulfonic acid (salt) group-containing polyester (sulfonic acid-modified polyester), copolymer of (meth)acrylic group-containing monomer and sulfonic acid (salt) group-containing monomer, and sulfonic acid (salt) group-containing allyl polymer.

Specific examples of the vinyl-based polymer include l alcohol, polyvinylpyrrolidone, and copolymer thereof.

Among these, the component (C) is still more preferably polyacrylic acid or polyvinyl alcohol.

Although there is no particular restriction on weight average molecular weight (Mw) of the component (C), it is preferably 1,000 or more, more preferably 3,000 or more, still more preferably 5,000 or more, even more preferably 8,000 or more, and particularly preferably 10,000 or more. In addition, the weight average molecular weight (Mw) of the component (C) is preferably 1,000,000 or less, more preferably 500,000 or less, still more preferably 300,000 or less, even more preferably 200,000 or less, and particularly preferably less than 200,000. That is, the weight average molecular weight (Mw) of the component (C) is preferably 1,000 or more and 1,000,000 or less, more preferably 3,000 or more and 500,000 or less, still more preferably 5,000 or more and 300,000 or less, even more preferably 8,000 or more and 200,000 or less, and particularly preferably 10,000 or more and less than 200,000. Note that the weight average molecular weight (Mw) of the component (C) can be measured as the value in terms of polyethylene glycol using gel permeation chromatography (GPC). The details of the measurement method are described in Examples.

Although there is no particular restriction on a concentration (content) of the component (C) in the polishing composition, it is preferable that the concentration (content) is 100 ppm by mass (0.01% by mass) or more, and it may be 150 ppm by mass (0.015% by mass) or more, 200 ppm by mass (0.02% by mass) or more, 250 ppm by mass (0.025% by mass) or more, 300 ppm by mass (0.03% by mass) or more, 400 ppm by mass (0.04% by mass) or more, 500 ppm by mass (0.05% by mass) or more, 600 ppm by mass (0.06% by mass) or more, 700 ppm by mass (0.07% by mass) or more, 800 ppm by mass (0.08% by mass) or more, 900 ppm by mass (0.09% by mass) or more, 1000 ppm by mass (0.1% by mass) or more, or 2000 ppm by mass (0.2% by mass) or more with respect to 100% by mass of the total mass of the polishing composition. In addition, although there is no particular restriction on the concentration (content) of the component (C) in the polishing composition, it is preferably 10,000 ppm by mass (1% by mass) or less, may be 8,000 ppm by mass (0.8% by mass) or less, 7,000 ppm by mass (0.7% by mass) or less, 6,000 ppm by mass (0.6% by mass) or less, 5,000 ppm by mass (0.5% by mass) or less, 4,500 ppm by mass (0.45% by mass) or less, 4,000 ppm by mass (0.4% by mass) or less, 3,500 ppm by mass (0.35% by mass) or less, 3,000 ppm by mass (0.3% by mass) or less, 2,000 ppm by mass (0.2% by mass) or less, or 1,000 ppm by mass (0.1% by mass) or less with respect to 100% by mass of the total mass of the polishing composition.

The concentration (content) of the component (C) in the polishing composition may be 100 ppm by mass (0.01% by mass) or more and 10,000 ppm by mass (1% by mass) or less, 200 ppm by mass (0.02% by mass) or more and 8,000 ppm by mass (0.8% by mass) or less, 300 ppm by mass (0.03% by mass) or more and 7,000 ppm by mass (0.7% by mass) or less, 500 ppm by mass (0.05% by mass) or more and 6,000 ppm by mass (0.6% by mass) or less, 800 ppm by mass (0.08% by mass) or more and 5,000 ppm by mass (0.5% by mass) or less, or 1,000 ppm by mass (0.1% by mass) or more and 4,000 ppm by mass (0.4% by mass) or less with respect to 100% by mass of the total mass of the polishing composition. Note that, in the case where the polishing composition contains two or more types of components (C), the concentration (content) of the component (C) is intended to be the total amount thereof.

### [(D) Polyoxyalkylene Compound]

The polishing composition according to the present disclosure contains (D) a polyoxyalkylene compound (component (D)). It is considered that the component (D), together with the component (C), forms a protective film on a surface of an object to be polished, and has a function of suppressing action of the isothiazolinone compound or the thiazolinone compound on the object to be polished.

Specific examples of the component (D) include homopolymer and copolymer of oxyalkylene, such as polyethylene glycol, polypropylene glycol, polytrimethylene glycol, polytetramethylene glycol, polypentamethylene glycol, polyhexamethylene glycol, polyheptamethylene glycol, polyoctamethylene glycol, polynonamethylene glycol, polydecamethylene glycol, polyethylene glycol-polypropylene glycol random copolymer, polyethylene glycol-polytetramethylene glycol random copolymer, polypropylene glycol-polytetramethylene glycol random copolymer, polyethylene glycol-polypropylene glycol-polytetramethylene glycol random copolymer, polyethylene glycol-polypropylene glycol block copolymer, polypropylene glycol-polyethylene glycol-polypropylene glycol triblock copolymer, and polyethylene glycol-polypropylene glycol-polyethylene glycol triblock copolymer.

In addition, polyoxyalkylene alkyl ether can also be used as the component (D). Specific examples thereof include polyoxyalkylene monoalkyl ether such as polyethylene glycol monomethyl ether, polypropylene glycol monomethyl ether, polytetramethylene glycol monomethyl ether, polyethylene glycol-polypropylene glycol monomethyl ether, polyethylene glycol monoethyl ether, polypropylene glycol monoethyl ether, polytetramethylene glycol monoethyl ether, polyethylene glycol-polypropylene glycol monoethyl ether, polyethylene glycol monopropyl ether, polypropylene glycol monopropyl ether, polytetramethylene glycol monopropyl ether, polyethylene glycol-polypropylene glycol monopropyl ether, polyethylene glycol monobutyl ether, polypropylene glycol monobutyl ether, polytetramethylene glycol monobutyl ether, polyethylene glycol-polypropylene glycol monobutyl ether, polyethylene glycol monopentyl ether, polypropylene glycol monopentyl ether, polyethylene glycol monohexyl ether, polypropylene glycol monohexyl ether, polyethylene glycol monooctyl ether, polypropylene glycol monooctyl ether, polyethylene glycol monononyl ether, polypropylene glycol monononyl ether, polyethylene glycol monodecyl ether, and polypropylene glycol monodecyl ether; and polyoxyalkylene dialkyl ether such as polyethylene glycol dimethyl ether, polypropylene glycol dimethyl ether, polytetramethylene glycol dimethyl ether, polyethylene glycol-polypropylene glycol dimethyl ether, polyethylene glycol diethyl ether, polypropylene glycol diethyl ether, polytetramethylene glycol diethyl ether, polyethylene glycol-polypropylene glycol diethyl ether, polyethylene glycol dipropyl ether, polypropylene glycol dipropyl ether, polytetramethylene glycol dipropyl ether, polyethylene glycol-polypropylene glycol dipropyl ether, polyethylene glycol dibutyl ether, polypropylene glycol dibutyl ether, polytetramethylene glycol dibutyl ether, polyethylene glycol-polypropylene glycol dibutyl ether, polyethylene glycol dipentyl ether, polypropylene glycol dipentyl ether, polyethylene glycol dihexyl ether, polypropylene glycol dihexyl ether, polyethylene glycol dioctyl ether, polypropylene glycol dioctyl ether, polyethylene glycol dinonyl ether, polypropylene glycol dinonyl ether, polyethylene glycol didecyl ether, and polypropylene glycol didecyl ether.

According to one preferable embodiment of the present disclosure, the component (D) is a compound represented by the following formula (1):

R₁O-(AO)ₙ—R² (1)
wherein
R¹ and R² are each independently a hydrogen atom or an alkyl group having 1 or more and 10 or less carbon atoms;
   AO is an oxyalkylene group having 2 or more and 4 or less carbon atoms; and
   n represents an average number of added moles of the oxyalkylene group and is a number of 2 or more and 20 or less.

According to one more preferable embodiment of the present disclosure, the component (D) is polyethylene glycol or polypropylene glycol.

Although there is no particular restriction on weight average molecular weight (Mw) of the component (D), it is preferably 100 or more, more preferably 150 or more, and may be 200 or more, 250 or more, 300 or more, 350 or more, or 400 or more. In addition, although there is no particular restriction on the weight average molecular weight (Mw) of the component (D), it is preferably 2,000 or less, and may be 1,500 or less, 1,000 or less, 900 or less, 800 or less, 700 or less, 600 or less, or 500 or less. The weight average molecular weight (Mw) of the component (D) can be measured as the value in terms of polyethylene glycol using gel permeation chromatography (GPC), and specifically, it can be measured by the method described in Examples.

Although there is no particular restriction on a concentration (content) of the component (D) in the polishing composition, it is preferably 50 ppm by mass (0.005% by mass) or more, and may be 100 ppm by mass (0.01% by mass) or more, 150 ppm by mass (0.015% by mass) or more, 200 ppm by mass (0.02% by mass) or more, 250 ppm by mass (0.025% by mass) or more, 300 ppm by mass (0.03% by mass) or more, 400 ppm by mass (0.04% by mass) or more, 500 ppm by mass (0.05% by mass) or more, 600 ppm by mass (0.06% by mass) or more, 700 ppm by mass (0.07% by mass) or more, 800 ppm by mass (0.08% by mass) or more, 900 ppm by mass (0.09% by mass) or more, or 1,000 ppm by mass (0.1% by mass) or more with respect to 100% by mass of the total mass of the polishing composition. In addition, although there is no particular restriction on the concentration (content) of the component (D) in the polishing composition, it is preferably 3,000 ppm by mass (0.3% by mass) or less, and may be 2,500 ppm by mass (0.25% by mass) or less, 2,000 ppm by mass (0.2% by mass) or less, 1,800 ppm by mass (0.18% by mass) or less, 1,500 ppm by mass (0.15% by mass) or less, 1,200 ppm by mass (0.12% by mass) or less, 1,000 ppm by mass (0.1% by mass) or less, 800 ppm by mass (0.08% by mass) or less, 600 ppm by mass (0.06% by mass) or less, 500 ppm by mass (0.05% by mass) or less, or 400 ppm by mass (0.04% by mass) or less with respect to 100% by mass of the total mass of the polishing composition.

Although there is no particular restriction on the concentration (content) of the component (D) in the polishing composition, it may be 100 ppm by mass (0.01% by mass) or more and 2,000 ppm by mass (0.2% by mass) or less, 200 ppm by mass (0.02% by mass) or more and 1,500 ppm by mass (0.15% by mass) or less, 300 ppm by mass (0.03% by mass) or more and 1,200 ppm by mass (0.12% by mass) or less, 300 ppm by mass (0.03% by mass) or more and 1,000 ppm by mass (0.1% by mass) or less, or 400 ppm by mass (0.04% by mass) or more and 800 ppm by mass (0.08% by mass) or less with respect to 100% by mass of the total mass of the polishing composition. Note that, in the case where the polishing composition contains two or more types of components (D), the concentration (content) of the component (D) is intended to be the total amount thereof.

### [Content Mass Ratio of Component (C) to Component (D) (Component (C)/Component (D))]

Although there is no particular restriction on a content mass ratio of the component (C) to the component (D) (component (C)/component (D)) in the polishing composition according to the present disclosure, from the viewpoint that the effect of the present disclosure is further demonstrated, it is preferably 0.01 or more, and may be 0.05 or more, 0.1 or more, 0.5 or more, 1 or more, or 2 or more. Although there is no particular restriction on the content mass ratio of the component (C) to the component (D) (component (C)/component (D)) in the polishing composition according to the present disclosure, it is preferably 50 or less, and may be 40 or less, 30 or less, 20 or less, 10 or less, or 8 or less.

The content mass ratio of the component (C) to the component (D) (component (C)/component (D)) in the polishing composition according to the present disclosure is preferably 0.01 or more and 50 or less, and may be 0.01 or more and 40 or less, 0.05 or more and 30 or less, 0.1 or more and 20 or less, 0.1 or more and 10 or less, 0.5 or more and 10 or less, 1 or more and 10 or less, 1 or more and 8 or less, or 2 or more and 8 or less.

### [pH and pH Adjusting Agent]

Although there is no particular restriction on pH of the polishing composition according to the present disclosure, it is preferably less than 7. The pH is preferably 6 or less, more preferably 5 or less, still more preferably 4 or less, and particularly preferably 3 or less. Also, the pH is preferably 1 or more, more preferably 1.5 or more, and still more preferably 2 or more. That is, the pH of the polishing composition according to the present disclosure is preferably 1 or more and less than 7, more preferably 1 or more and 6 or less, still more preferably 1 or more and 5 or less, even more preferably 1.5 or more and 4 or less, even more preferably 1.5 or more and 3 or less, and particularly preferably 2 or more and 3 or less.

The polishing composition according to the present disclosure may contain a pH adjusting agent for adjusting pH. The pH adjusting agent may be either an acid or a base, and may be either an inorganic compound or an organic compound. As the pH adjusting agent, one type alone may be used or a combination of two or more types may be used.

Specific examples of the acid that can be used as the pH adjusting agent include: inorganic acids such as hydrochloric acid, sulfuric acid, nitric acid, hydrofluoric acid, boric acid, carbonic acid, hypophosphorous acid, phosphorous acid, and phosphoric acid; and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid.

Examples of the base that can be used as the pH adjusting agent include amine such as aliphatic amines and aromatic amines, hydroxides of alkali metals such as sodium hydroxide and potassium hydroxide, hydroxides of alkaline earth metals, and ammonia.

There is no particular restriction on an amount of the pH adjusting agent added, and it may be adjusted as appropriate so that the polishing composition has desired pH. Also, the pH of the polishing composition can be measured with a pH meter, for example, and specifically, it can be measured by the method described in Examples.

Note that the inorganic salt and organic onium salt described below can also serve as the pH adjusting agent.

### [Dispersing Medium]

It is preferable that the polishing composition according to the present disclosure contains a dispersing medium for dispersing each component. Examples of the dispersing medium can include: water; alcohols such as methanol, ethanol, and ethylene glycol; ketones such as acetone; and mixtures thereof. Of these, water is preferable as the dispersing medium. That is, according to preferable embodiment of the present disclosure, the dispersing medium contains water. According to more preferable embodiment of the present disclosure, the dispersing medium consists essentially of water. Note that the term “essentially” described above is intended to mean that a dispersing medium other than water can be included as long as the effect of the present disclosure can be achieved. More specifically, the dispersing medium preferably consists of 90% by mass or more and 100% by mass or less of water and 0% by mass or more and 10% by mass or less of a dispersing medium other than water, and more preferably consists of 99% by mass or more and 100% by mass or less of water and 0% by mass or more and 1% by mass or less of a dispersing medium other than water. Most preferably, the dispersing medium is water.

From the viewpoint of not inhibiting the action of the components contained in the polishing composition, the dispersing medium is preferably water containing as few impurities as possible. Specifically, ion exchanged water (deionized water), pure water or ultrapure water, which is obtained by removing impurity ions with an ion exchange resin and then passing the water through a filter to remove foreign matter, or distilled water is more preferable.

### [Other Components]

The polishing composition according to the present disclosure may further contain, or may not contain, other components such as an inorganic salt, an organic onium salt, a complexing agent, a metal anticorrosive, a reducing agent, and a surfactant, within a range that does not inhibit the effect of the present disclosure. Hereinafter, the preferable components, inorganic salt and organic onium salt, will be described. In addition, an oxidizing agent will also be described.

### (Inorganic Salt)

It is preferable that the polishing composition according to the present disclosure further contains an inorganic salt. The inorganic salt has the function of increasing the electrical conductivity of the polishing composition to further improve the polishing removal rate for an object to be polished.

Examples of the inorganic salt include inorganic salts composed of the cations and anions listed below. Examples of the cations include alkali metal ions such as lithium ion, sodium ion, and potassium ion, alkaline earth metal ions such as magnesium ion, calcium ion, and strontium ion, polyatomic ions such as ammonium ion, and complex ions. Examples of the anions include halide ions (such as fluoride ion, chloride ion, bromide ion, and iodide ion), oxoacid ions (borate ion, carbonate ion, nitrate ion, nitrite ion, metasilicate ion, phosphate ion, monohydrogen phosphate ion, dihydrogen phosphate ion, phosphonate ion, monohydrogen phosphonate ion, phosphinate ion, sulfate ion, sulfonate ion, sulfite ion, thiosulfate ion, chromate ion, dichromate ion, and permanganate ion), thiocyanate ion, cyanate ion, and sulfamate ion.

Further specific examples of the inorganic salt include: lithium salts such as lithium chloride, lithium bromide, lithium carbonate, lithium nitrate, and lithium thiocyanate; calcium salts such as calcium chloride, calcium bromide, calcium carbonate, calcium nitrate, and calcium thiocyanate; iron salts such as iron nitrate and iron thiocyanate; potassium salts such as potassium chloride, potassium bromide, potassium nitrate, potassium sulfate, potassium thiocyanate, potassium sulfamate, potassium phosphate, potassium dihydrogen phosphate, potassium monohydrogen phosphate, and potassium monohydrogen phosphonate; sodium salts such as sodium chloride, sodium bromide, sodium nitrate, sodium sulfate, and sodium thiocyanate; zinc salts such as zinc chloride, zinc nitrate, and zinc thiocyanate; magnesium salts such as magnesium nitrate, magnesium sulfate, and magnesium thiocyanate; strontium salts such as strontium nitrate and strontium thiocyanate; and ammonium salts such as ammonium chloride, ammonium bromide, ammonium iodide, ammonium nitrate, ammonium phosphate, ammonium dihydrogen phosphate, diammonium hydrogen phosphate, ammonium phosphonate, ammonium monohydrogen phosphonate, ammonium sulfate, ammonium thiocyanate, and ammonium sulfamate. These inorganic salts may be used alone as one type, or may be used in combination of two or more types. In addition, commercial products of the inorganic salt may be used and synthetic products thereof may also be used.

Among these, from the viewpoint of further improving the polishing removal rate, the inorganic salt is more preferably at least one selected from the group consisting of ammonium sulfate, ammonium nitrate, ammonium carbonate, diammonium hydrogen phosphate, potassium sulfate, potassium nitrate, and potassium carbonate, and still more preferably ammonium sulfate or diammonium hydrogen phosphate.

Although there is no particular restriction on a concentration (content) of the inorganic salt in the polishing composition, it is preferably 100 ppm by mass (0.01% by mass) or more, more preferably 300 ppm by mass (0.03% by mass) or more, still more preferably 500 ppm by mass (0.05% by mass) or more, and particularly preferably 1,000 ppm by mass (0.1% by mass) or more with respect to 100% by mass of the total mass of the polishing composition. Also, the upper limit of the concentration (content) of the inorganic salt in the polishing composition is preferably 20,000 ppm by mass (2.0% by mass) or less, more preferably 10,000 ppm by mass (1.0% by mass) or less, still more preferably 8,000 ppm by mass (0.8% by mass) or less, and particularly preferably 6,000 ppm by mass (0.6% by mass) or less with respect to 100% by mass of the total mass of the polishing composition.

That is, the concentration (content) of the inorganic salt is preferably 100 ppm by mass (0.01% by mass) or more and 20,000 ppm by mass (2.0% by mass) or less, more preferably 300 ppm by mass (0.03% by mass) or more and 10,000 ppm by mass (1.0% by mass) or less, still more preferably 500 ppm by mass (0.05% by mass) or more and 8,000 ppm by mass (0.8% by mass) or less, and particularly preferably 1,000 ppm by mass (0.1% by mass) or more and 6,000 ppm by mass (0.6% by mass) or less with respect to the total mass of the polishing composition.

Note that, in the case where the polishing composition contains two or more types of inorganic salts, the concentration (content) of the inorganic salt means their total amount.

### (Organic Onium Salt)

The polishing composition according to the present disclosure may contain, or may not contain, an organic onium salt. The organic onium salt has a function of reducing defects (foreign matter, scratches, and the like) on the surface of an object to be polished that has been polished (a polished object).

The organic onium salt used in the present disclosure is preferably at least one of a tetraalkylammonium salt represented by the following chemical formula 1 and a tetraalkylphosphonium salt represented by the following chemical formula 2.

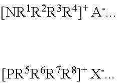

In the above chemical formula 1 and chemical formula 2,
R¹ to R⁸ are each independently an unsubstituted alkyl group having 1 or more and 4 or less carbon atoms, and
A⁻ and X⁻ are each independently a monovalent anion.

Specific examples of the unsubstituted alkyl group having 1 or more and 4 or less carbon atoms for R¹ to R⁸ in the above chemical formula 1 and chemical formula 2 include a methyl group, an ethyl group, a n-propyl group, an isopropyl group, a n-butyl group, a sec-butyl group, an isobutyl group, and a tert-butyl group. From the viewpoint that the effect of the present disclosure is further demonstrated, unsubstituted alkyl groups having 2 or more and 4 or less carbon atoms are preferable, such as an ethyl group, a n-propyl group, an isopropyl group, a n-butyl group, a sec-butyl group, an isobutyl group, and a tert-butyl group.

Suitable examples of the monovalent anion for A⁻ and X⁻ in the above chemical formula 1 and chemical formula 2 include, but are not particularly restricted to, halide ions such as fluoride ion, chloride ion, bromide ion, and iodide ion; hydroxide ion; and organic acid ions such as benzoic acid ion. The monovalent anion may be one type alone or a combination of two or more types. From the viewpoint that the effect of the present disclosure is further demonstrated, A⁻ and X⁻ in the above chemical formula 1 and chemical formula 2 are preferably hydroxide ions (OH⁻).

The organic onium salt may be used alone as one type, or may be used in combination of two or more types. In addition, commercial products of the organic onium salt may be used and synthetic products thereof may also be used.

Among these organic onium salts, from the viewpoint of more easily demonstrating the effect of the defect reduction, the organic onium salt is preferably a tetraalkylammonium salt represented by the above chemical formula 1, and more preferably at least one selected from the group consisting of tetraethylammonium hydroxide, tetrapropylammonium hydroxide, and tetra-n-butylammonium hydroxide.

The lower limit of a concentration (content) of the organic onium salt in the polishing composition is preferably 10 ppm by mass (0.001% by mass) or more, more preferably 15 ppm by mass (0.0015% by mass) or more, still more preferably 20 ppm by mass (0.002% by mass) or more, and particularly preferably 25 ppm by mass (0.0025% by mass) or more with respect to the total mass of the polishing composition. Also, the upper limit of the concentration (content) of the organic onium salt in the polishing composition is preferably 1000 ppm by mass (0.1% by mass) or less, more preferably 500 ppm by mass (0.05% by mass) or less, still more preferably 300 ppm by mass (0.03% by mass) or less, and particularly preferably 100 ppm by mass (0.01% by mass) or less with respect to the total mass of the polishing composition.

That is, the concentration (content) of the organic onium salt in the polishing composition is preferably 10 ppm by mass (0.001% by mass) or more and 1000 ppm by mass (0.1% by mass) or less, more preferably 15 ppm by mass (0.015% by mass) or more and 500 ppm by mass (0.05% by mass) or less, still more preferably 20 ppm by mass (0.002% by mass) or more and 300 ppm by mass (0.03% by mass) or less, and particularly preferably 25 ppm by mass (0.0025% by mass) or more and 100 ppm by mass (0.01% by mass) or less with respect to the total mass of the polishing composition.

Note that, in the case where the polishing composition contains two or more types of organic onium salts, the concentration (content) of the organic onium salt means their total amount. (Oxidizing Agents)

It is preferable that the polishing composition according to the present disclosure is substantially free of oxidizing agents. If an oxidizing agent is contained in the polishing composition, it may oxidize the surface of an object to be polished, producing an oxide film and prolonging the polishing time. Specific examples of the oxidizing agents here include hydrogen peroxide (H₂O₂), sodium persulfate, ammonium persulfate, and sodium dichloroisocyanurate. Note that the polishing composition being substantially free of oxidizing agents means that the polishing composition does not contain an oxidizing agent at least intentionally. Accordingly, polishing compositions that unavoidably contain a trace amount of oxidizing agents due to the raw materials, production method, and other factors are encompassed in the concept of the polishing composition that is substantially free of oxidizing agents here. For example, a concentration (content) of oxidizing agent in the polishing composition is preferably 100 ppm by mass (0.01% by mass) or less, more preferably less than 100 ppm by mass (0.01% by mass), and still more preferably 50 ppm by mass (0.005% by mass) or less. The lower limit of the concentration (content) of oxidizing agent is preferably 0 ppm by mass or more, and more preferably 5 ppm by mass (0.0005% by mass) or more.

In one embodiment of the present disclosure, the polishing composition consists essentially of (A) abrasive grains, (B) a biocide (at least one selected from the group consisting of an isothiazolinone compound and a thiazolinone compound), (C) a polishing removal rate improver for a material having a silicon-silicon bond (a water-soluble polymer other than the component (D)), (D) a polyoxyalkylene compound, a dispersing medium, and at least one selected from the group consisting of a pH adjusting agent, an inorganic salt, and an organic onium salt. Here, the expression “the polishing composition consists essentially of (A) abrasive grains, (B) a biocide (at least one selected from the group consisting of an isothiazolinone compound and a thiazolinone compound), (C) a polishing removal rate improver for a material having a silicon-silicon bond (a water-soluble polymer other than the component (D)), (D) a polyoxyalkylene compound, a dispersing medium, and at least one selected from the group consisting of apH adjusting agent, an inorganic salt, and an organic onium salt” is intended to mean that the total content of (A) the abrasive grains, (B) the biocide (at least one selected from the group consisting of an isothiazolinone compound and a thiazolinone compound), (C) the polishing removal rate improver for a material having a silicon-silicon bond (a water-soluble polymer other than the component (D)), (D) the polyoxyalkylene compound, the dispersing medium, the pH adjusting agent, the inorganic salt, and the organic onium salt is more than 99% by mass (upper limit: 100% by mass) with respect to the total mass of the polishing composition. Preferably, the polishing composition consists of (A) abrasive grains, (B) a biocide (at least one selected from the group consisting of an isothiazolinone compound and a thiazolinone compound), (C) a polishing removal rate improver for a material having a silicon-silicon bond (a water-soluble polymer other than the component (D)), (D) a polyoxyalkylene compound, a dispersing medium, a pH adjusting agent, and an inorganic salt (the above total content=100% by mass).

### [Form of Polishing Composition]

The polishing composition according to the present disclosure is typically supplied to an object to be polished in the form of a polishing solution containing the polishing composition, and is used for polishing that object to be polished. The polishing composition according to the present disclosure may, for example, be diluted (typically diluted with water) and used as a polishing solution, or it may be used as is as a polishing solution. That is, the concept of the polishing composition according to the present disclosure encompasses both a polishing composition (working slurry) that is supplied to an object to be polished and used for polishing the object to be polished, and a concentrated solution (working slurry stock solution) that is diluted and then used for polishing. A concentration magnification of the above concentrated solution can be, for example, about 2 times or more and 100 times or less on a volume basis, and normally, about 3 times or more and 50 times or less is appropriate.

### [Object to be Polished]

The polishing composition according to one embodiment of the present disclosure is not particularly restricted, and can be applied to a known object to be polished that is used in the CMP field. For this reason, although the aspect of an object to be polished is not particularly restricted, a layer that is a flat plate-shaped member is preferable, a substrate including such a layer is more preferable, and a semiconductor substrate is still more preferable. Examples thereof include a substrate composed of a single layer, and a substrate including a layer to be polished and another layer (for example, a support layer or another functional layer). Although there is no particular restriction on the material that constitutes an object to be polished, examples thereof include a silicon-containing material, a metal-containing material (for example, a metal simple substance, a metal oxide, a metal nitride, and the like), and a carbon-containing material. The material that constitutes the object to be polished may be of a single type, or a combination of two or more types. In addition, as the object to be polished, commercial products may be used, or it may be produced by a known method.

Although there is no particular restriction on the silicon-containing material, examples thereof include a material having a silicon-oxygen bond, a material having a silicon-silicon bond, and a material having a silicon-nitrogen bond.

Although there is no particular restriction on the material having a silicon-oxygen bond, examples thereof include silicon oxide, BD (black diamond: SiOCH), FSG (fluorosilicate glass), HSQ (hydrogen silsesquioxane), CYCLOTENE, SiLK, and MSQ (methyl silsesquioxane). Further, examples of the film that contains silicon oxide include a TEOS (Tetraethyl Orthosilicate)-type silicon oxide film (hereinafter, also simply referred to as “TEOS film”), which is formed using tetraethyl orthosilicate as a precursor, a HDP (High Density Plasma) film, an USG (Undoped Silicate Glass) film, a PSG (Phosphorus Silicate Glass) film, a BPSG (Boron-Phospho Silicate Glass) film, and a RTO (Rapid Thermal Oxidation film).

Although there is no particular restriction on the material having a silicon-silicon bond, examples thereof include polycrystalline silicon (polysilicon, Poly-Si), amorphous silicon (a-Si), monocrystalline silicon, n-type impurity-doped monocrystalline silicon, p-type impurity-doped monocrystalline silicon, and a Si-based alloy such as SiGe.

Although there is no particular restriction on the material having a silicon-nitrogen bond, examples thereof include silicon nitride and silicon carbonitride (SiCN).

Examples of the metal-containing material include a metal simple substance such as tungsten, copper, aluminum, cobalt, hafnium, nickel, gold, silver, platinum, palladium, rhodium, ruthenium, iridium, and osmium, and an oxide and a nitride thereof.

Examples of the carbon-containing materials include amorphous carbon, spin-on carbon (SOC), diamond-like carbon (DLC), nanocrystalline diamond, and graphene.

Among these, an object to be polished including a material having a silicon-silicon bond is preferable. Hence, according to one preferable embodiment of the present disclosure, the polishing composition is used for the application where the object to be polished including a material having a silicon-silicon bond is polished. It is also preferable that the object to be polished further contains, in addition to the material having a silicon-silicon bond, at least one selected from a material having a silicon-oxygen bond and a material having a silicon-nitrogen bond.

### [Method for Producing Polishing Composition]

There is no particular restriction on the method for producing the polishing composition according to the present disclosure, and it can be obtained by, for example, stirring and mixing the components (A) to (D), and other components, if necessary, in the dispersing medium (for example, water). The details of each component are as described above.

There is no particular restriction on the temperature at which each component is mixed, but it is preferably 10° C. or higher and 40° C. or lower, and may be heated to increase the rate of dissolution. There is no particular restriction on the mixing time either, as long as uniform mixing can be achieved.

### [Polishing Method]

As described above, the polishing composition according to the present disclosure is suitably used for polishing an object to be polished including a material having a silicon-silicon bond. Hence, the present disclosure provides a polishing method including polishing an object to be polished including a material having a silicon-silicon bond with the polishing composition according to the present disclosure. The present disclosure also provides a method for producing a substrate, including polishing an object to be polished including a material having a silicon-silicon bond by the polishing method according to the present disclosure.

The polishing apparatus that can be used may be any general polishing apparatus to which a holder that holds a substrate or the like having an object to be polished, a motor whose rotation speed can be changed, and other components are attached, and that have a platen (polishing table) to which a polishing pad (polishing cloth) can be pasted.

There is no particular restriction on the type of polishing pad used in the polishing method and the method for producing a semiconductor substrate according to the present disclosure, and for example, a foamed polyurethane type, a non-woven fabric type, a suede type, and the like can be used.

Regarding the polishing conditions, for example, a rotation speed of the platen (polishing table) is preferably 10 rpm (0.17 s⁻¹) or more and 500 rpm (8.33 s⁻¹) or less. A pressure applied to the substrate having an object to be polished (polishing pressure) is preferably 0.5 psi (3.4 kPa) or more and 10 psi (68.9 kPa) or less. There is no particular restriction on method for supplying the polishing composition to the polishing pad either, and for example, a method is employed in which the polishing composition is continuously supplied with a pump or the like. There is no restriction on an amount supplied, but it is preferable that the surface of the polishing pad is always covered with the polishing composition according to the present disclosure.

After completion of polishing, the substrate is cleaned in running water, water droplets adhered onto the substrate are removed using a spin dryer or the like for drying, and thus the substrate that contains a material having a silicon-silicon bond is obtained.

The polishing composition according to the present disclosure may be of a one-pack type or multi-pack type including two-pack type. Also, the polishing composition according to the present disclosure may be prepared by, for example, diluting a stock solution of the polishing composition by about 2 times or more and 10 times or less, using a diluent such as water.

### [Polishing Removal Rate]

As described above, the polishing composition according to the present disclosure can realize a good polishing removal rate for a material having a silicon-silicon bond.

In the present disclosure, polishing removal rate for a material having a silicon-silicon bond (for example, polysilicon) is preferably 250 Å/min or more, more preferably 280 Å/min or more, and still more preferably 300 Å/min or more. Also, polishing removal rate for a material having a silicon-oxygen bond (for example, silicon oxide) is preferably 250 Å/min or more, more preferably 300 Å/min or more, and still more preferably 320 Å/min or more. Furthermore, polishing removal rate for a material having a silicon-nitrogen bond (for example, silicon nitride) is preferably 260 Å/min or more, more preferably 400 Å/min or more, and still more preferably 450 Å/min or more. Note that 1 Å=0.1 nm.

The polishing composition according to the present disclosure shows little change in polishing removal rate even after long-term storage, and can stably maintain polishing performance. For example, in a comparison between before storage and after storage at 25° C. for 317 days, rate of change in polishing removal rate for a material having a silicon-silicon bond (for example, polysilicon) is preferably within ±5%, more preferably within ±3%, and still more preferably within ±1%. The rate of change in polishing removal rate can be calculated by the method described in Examples.

The embodiments of the present disclosure are described in detail above, but are given for explanatory and illustrative purposes only, and are not limited. The scope of the present disclosure should be obviously construed on the basis of the attached claims.

The present disclosure encompasses the following aspects and forms.
[1] A polishing composition contains:
   (A) abrasive grains;
   (B) a biocide;
   (C) a polishing removal rate improver for a material having a silicon-silicon bond; and
   (D) a polyoxyalkylene compound,
   wherein the component (B) is at least one selected from the group consisting of an isothiazolinone compound and a thiazolinone compound, and
   wherein the component (C) is a water-soluble polymer other than the component (D).
[2] The polishing composition according to the above [1], wherein the component (C) is at least one selected from the group consisting of an anionic water-soluble polymer and a nonionic water-soluble polymer other than the component (D).
[3] The polishing composition according to the above [1] or [2], wherein the component (C) is at least one selected from the group consisting of polycarboxylic acid, polycarboxylic acid amide, polycarboxylic acid ester, polycarboxylic acid salt, polysulfonic acid, polyphosphonic acid, and vinyl-based polymer.
[4] The polishing composition according to any of the above [1] to [3], wherein the component (C) is polyacrylic acid or polyvinyl alcohol.
[5] The polishing composition according to any of the above [1] to [4], wherein a concentration of the component (C) is 500 ppm by mass or more with respect to a total mass of the polishing composition.
[6] The polishing composition according to any of the above [1] to [5], wherein the component (D) is a compound represented by the following formula (1):

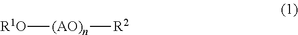

wherein
R¹ and R² are each independently a hydrogen atom or an alkyl group having 1 or more and 10 or less carbon atoms;
AO is an oxyalkylene group having 2 or more and 4 or less carbon atoms; and
n represents an average number of added moles of the oxyalkylene group and is a number of 2 or more and 20 or less.
[7] The polishing composition according to any of the above [1] to [6], wherein the component (D) is polyethylene glycol or polypropylene glycol.
[8] The polishing composition according to any of the above [1] to [7], wherein a concentration of the component (D) is 200 ppm by mass or more with respect to a total mass of the polishing composition.
[9] The polishing composition according to any of the above [1] to [8], wherein a content mass ratio of the component (C) to the component (D) (component (C)/component (D)) is 0.1 or more and 10 or less.
[10] The polishing composition according to any of the above [1] to [9], wherein the abrasive grains are sulfonic acid-modified colloidal silica.
[11] The polishing composition according to any of the above [1] to [10], further containing a dispersing medium.
[12] The polishing composition according to any of the above [1] to [11], wherein pH of the polishing composition is 1 or more and 5 or less.
[13] The polishing composition according to any of the above [1] to [12], wherein pH of the polishing composition is 1.5 or more and 3 or less.
[14] The polishing composition according to any of the above [1] to [13], used for polishing an object to be polished including a material having a silicon-silicon bond.
[15] The polishing composition according to the above [14], wherein the object to be polished further contains at least one selected from a material having a silicon-oxygen bond and a material having a silicon-nitrogen bond.
[16] A polishing method including polishing an object to be polished including a material having a silicon-silicon bond, using the polishing composition set forth in any of the above [1] to [15].

### EXAMPLES

The present disclosure will be described in further detail using the following Examples and Comparative Examples. However, the technical scope of the present disclosure is not limited to the following Examples. Note that, unless otherwise specified, “%” and “part(s)” refer to “% by mass” and “parts by mass”, respectively.

### <Average Primary Particle Size and Average Secondary Particle Size of Abrasive Grains>

The average primary particle size (diameter) of the abrasive grains was calculated from the specific surface area of the abrasive grains by the BET method measured using Flow Sorb II 2300 manufactured by Micromeritics Instrument Corporation and the density of the abrasive grains. Also, the average secondary particle size (diameter) of the abrasive grains was measured as the volume average particle size (arithmetic mean size on a volume basis; Mv) using the dynamic light scattering particle size and particle size distribution apparatus UPA-UT151 (manufactured by Nikkiso Co., Ltd.).

### <Zeta Potential of Abrasive Grains>

The zeta potential of the abrasive grains in the polishing composition was calculated by subjecting the polishing composition to Zetasizer Nano manufactured by Malvern Panalytical, performing measurement by the laser Doppler method (electrophoretic light scattering measurement method) under conditions of a measurement temperature of 25° C., and analyzing the obtained data with the Smoluchowski equation for calculation.

### <pH of Polishing Composition>

The pH of the polishing composition was measured with a pH meter (manufactured by HORIBA, Ltd., model number: LAQUA).

### <Weight Average Molecular Weight of Component (C) and Component (D)>

The weight average molecular weight of the component (C) and component (D) were measured using gel permeation chromatography (GPC) under the following measurement conditions.

### (GPC Measurement Conditions)

Measurement apparatus: HLC-8320GPC (manufactured by TOSOH CORPORATION)

Sample concentration: 0.01% by mass

Column: TSKgel (R) GMPWXL

Detector: differential refractometer

Eluent: solution of 10 mM lithium bromide dissolved in N,N-dimethylformamide

Flow rate: 1 mL/min

Measurement temperature: 40° C.

Molecular weight conversion: in terms of polyethylene glycol

Sample injection volume: 200 μL

### [Production of Sulfonic Acid-Modified Colloidal Silica (Abrasive Grain 1)]

Using colloidal silica having an average primary particle size of 34 nm and an average secondary particle size of 70 nm, sulfonic acid-modified colloidal silica was prepared, which was made by the method described in “Sulfonic acid-functionalized silica through quantitative oxidation of thiol groups,” Chem. Commun. 246-247 (2003).

### [Production of Sulfonic Acid-Modified Colloidal Silica (Abrasive Grains 2)]

Using colloidal silica having an average primary particle size of 15 nm and an average secondary particle size of 35 nm, sulfonic acid-modified colloidal silica was prepared, which was made by the method described in “Sulfonic acid-functionalized silica through quantitative oxidation of thiol groups,” Chem. Commun. 246-247 (2003).

### Example 1

To water as the dispersing medium, the sulfonic acid-modified colloidal silica (abrasive grain 1, average primary particle size: 34 nm, average secondary particle size: 70 nm), which was produced in the above [Production of Sulfonic Acid-Modified Colloidal Silica (Abrasive Grain 1)], was added as the component (A) so that the final concentration was 4% by mass, and a mixed solution was obtained. To this mixed solution, ammonium sulfate ((NH₄)₂SO₄) as the inorganic salt was added so that the final concentration was 2,000 ppm by mass (0.2% by mass). Furthermore, 1,2-benzisothiazol-3 (2H)-one (BIT) as the component (B), polyvinyl alcohol (PVA) having a weight average molecular weight (Mw) of 10,000 as the component (C), and polypropylene glycol (PPG2) having a weight average molecular weight (Mw) of 400 as the component (D) were added so that the respective final concentrations were 120 ppm by mass (0.012% by mass), 1,000 ppm by mass (0.1% by mass), and 600 ppm by mass (0.06% by mass), and the mixture was stirred and mixed (stirring temperature: 25° C., stirring time: 20 minutes). Thereafter, pH of the polishing composition was adjusted to 3.0 using nitric acid to prepare a polishing composition 1.

### Example 2

A polishing composition 2 was prepared in the same manner as in Example 1, except that polyacrylic acid (PA1) having a weight average molecular weight (Mw) of 25,000 was added as the component (C) in place of PVA so that the final concentration was 3,000 ppm by mass (0.3% by mass), the amount of polypropylene glycol (PPG2), which is the component (D), added was changed to such an amount that the final concentration was 500 ppm by mass (0.05% by mass), and the amount of nitric acid added was changed to such an amount that pH of the polishing composition was 2.1.

### Example 3

In place of the abrasive grains 1, the sulfonic acid-modified colloidal silica (abrasive grains 2, average primary particle size: 15 nm, average secondary particle size, average secondary particle size: 35 nm), which was produced in the above [Production of Sulfonic Acid-Modified Colloidal Silica (Abrasive Grains 2)], was added as the component (A) so that the final concentration was 6% by mass. Further, except that diammonium hydrogen phosphate ((NH₄)₂HPO₄) was added as the inorganic salt in place of ammonium sulfate so that the final concentration was 4,000 ppm by mass (0.4% by mass), a polishing composition 3 was prepared in the same manner as in Example 2.

### Example 4

A polishing composition 4 was prepared in the same manner as in Example 3, except that the amount of polyacrylic acid (PA1) added was changed to such an amount that the final concentration was 500 ppm by mass (0.05% by mass).

### Example 5

A polishing composition 5 was prepared in the same manner as in Example 3, except that the amount of polyacrylic acid (PA1) added was changed to such an amount that the final concentration was 200 ppm by mass (0.02% by mass).

### Example 6

A polishing composition 6 was prepared in the same manner as in Example 3, except that the amount of polypropylene glycol (PPG2) added was changed to such an amount that the final concentration was 1,000 ppm by mass (0.1% by mass).

### Example 7

A polishing composition 7 was prepared in the same manner as in Example 3, except that the amount of polypropylene glycol (PPG2) added was changed to such an amount that the final concentration was 300 ppm by mass (0.03% by mass).

### Example 8

A polishing composition 8 was prepared in the same manner as in Example 3, except that the amount of polypropylene glycol (PPG2) added was changed to such an amount that the final concentration was 100 ppm by mass (0.01% by mass).

### Example 9

A polishing composition 9 was prepared in the same manner as in Example 3, except that polyacrylic acid (PA2) having a weight average molecular weight (Mw) of 150,000 was added as the component (C) in place of polyacrylic acid (PA1) so that the final concentration was 3,000 ppm by mass (0.3% by mass).

### Example 10

A polishing composition 10 was prepared in the same manner as in Example 3, except that polypropylene glycol (PPG1) having a weight average molecular weight (Mw) of 200 was added as the component (D) in place of polypropylene glycol (PPG2) so that the final concentration was 500 ppm by mass (0.05% by mass).

### Example 11

A polishing composition 11 was prepared in the same manner as in Example 3, except that polypropylene glycol (PPG3) having a weight average molecular weight (Mw) of 600 was added as the component (D) in place of polypropylene glycol (PPG2) so that the final concentration was 500 ppm by mass (0.05% by mass).

### Example 12

A polishing composition 12 was prepared in the same manner as in Example 3, except that polyethylene glycol (PEG) having a weight average molecular weight (Mw) of 600 was added as the component (D) in place of polypropylene glycol (PPG2) so that the final concentration was 500 ppm by mass (0.05% by mass).

### Example 13

A polishing composition 13 was prepared in the same manner as in Example 3, except that polyvinyl alcohol (PVA) having a weight average molecular weight (Mw) of 10,000 was added as the component (C) in place of polyacrylic acid (PA1) so that the final concentration was 3,000 ppm by mass (0.3% by mass).

### Example 14

To water as the dispersing medium, the sulfonic acid-modified colloidal silica (abrasive grains 1, average primary particle size: 34 nm, average secondary particle size: 70 nm), which was produced in the above [Production of Sulfonic Acid-Modified Colloidal Silica (Abrasive Grains 1)], was added as the component (A) so that the final concentration was 2% by mass, and a mixed solution was obtained. To this mixed solution, ammonium sulfate ((NH₄)₂SO₄) was added as the inorganic salt so that the final concentration was 5,000 ppm by mass (0.5% by mass). Furthermore, 1,2-benzisothiazol-3 (2H)-one (BIT) as the component (B), polyacrylic acid (PA1) having a weight average molecular weight (Mw) of 25,000 as the component (C), and polyethylene glycol (PEG) having a weight average molecular weight (Mw) of 600 as the component (D) were added so that the respective final concentrations were 120 ppm by mass (0.012% by mass), 500 ppm by mass (0.05% by mass), and 300 ppm by mass (0.03% by mass), and the mixture was stirred and mixed (stirring temperature: 25° C., stirring time: 20 minutes). Thereafter, pH of the polishing composition was adjusted to 2.2 using nitric acid to prepare a polishing composition 14.

### Comparative Example 1

A polishing composition comparative 1 was prepared in the same manner as in Example 3, except that 1,2-benzisothiazol-3 (2H)-one (BIT) was not added.

### Comparative Example 2

A polishing composition comparative 2 was prepared in the same manner as in Example 3, except that polyacrylic acid (PA1) and polypropylene glycol (PPG2) were not added.

### Comparative Example 3

A polishing composition comparative 3 was prepared in the same manner as in Example 3, except that polypropylene glycol (PPG2) was not added.

### Comparative Example 4

A polishing composition comparative 4 was prepared in the same manner as in Example 3, except that polyacrylic acid (PA1) was not added.

### [Evaluation]

### <Measurement of Polishing Removal Rate (Before Storage)>

Using the polishing compositions of Examples and Comparative Examples obtained as described above, polishing of objects to be polished was carried out under the following polishing conditions. Note that, as the objects to be polished, a silicon wafer (300 mm, blanket wafer) having a P-TEOS film (TEOS film (silicon oxide film) formed by plasma CVD) with a thickness of 10,000 Å formed on the surface thereof, a silicon wafer (300 mm, blanket wafer) having a polysilicon (Poly-Si) film with a thickness of 5,000 Å formed on the surface thereof, and a silicon wafer (300 mm, blanket wafer) having a silicon nitride (SiN) film with a thickness of 3,000 Å formed on the surface thereof were used.

### (Polishing Conditions)

Polishing machine: FREX 300E manufactured by Ebara Corporation

Pad: rigid polyurethane pad IC1010 manufactured by NITTA DuPont Incorporated.

Polishing pressure: 2.0 psi (1 psi=6894.76 Pa, the same applies hereinafter)

Rotation speed of platen (polishing table): 90 rpm

Rotation speed of carrier: 90 rpm

Supply of polishing composition: flowing

Amount of polishing composition supplied: 200 mL/min

Polishing time: 1 minute

The polishing removal rate was calculated by determining the thickness of the object to be polished before and after polishing with an optical film thickness measuring instrument (RE-3500: manufactured by SCREEN Semiconductor Solutions Co., Ltd.) and dividing [(thickness before polishing)−(thickness after polishing)] by the polishing time.

### [Rate of Change in Polishing Removal Rate]

The polishing compositions of Examples and Comparative Examples obtained as described above were filled into transparent polyethylene containers, sealed, and allowed to stand in an environment at 80° C. for one week, followed by cooling to room temperature. Using the polishing compositions obtained after this cooling, polishing of the Poly-Si substrate was carried out under the same polishing conditions as described above, and the polishing removal rate (polishing removal rate after storage) was measured. From the polishing removal rate before storage measured as described above and the polishing removal rate after storage, the rate of change in polishing removal rate was calculated according to the following expression.

Rate of change in polishing removal rate [%]={(Polishing removal rate after storage [Å/min]−Polishing removal rate before storage [Å/min])/Polishing removal rate before storage [Å/min]}×100

Note that the storage conditions at 80° C. for 1 week (7 days) correspond to storage at 25° C. for 317 days, based on conversion according to the Arrhenius equation.

### [Antiseptic Performance]

In order to evaluate the antiseptic performance of each polishing composition, the following test was carried out in which microorganisms were forcibly added and cultured for a certain period of time. That is, 2 g of industrial water inoculated with seed microorganisms (total bacterial count of 10⁸ cells/mL or more) was added to 50 g of each undiluted polishing composition, and the mixture was allowed to stand at 35° C. for 10 days. Thereafter, the number of viable bacteria under the culture conditions at 35° C. for 10 days was measured using Biochecker manufactured by San-Ai Oil Co., Ltd. (model: San-Ai Biochecker TTC), and evaluated according to the following criteria.

◯: No viable bacteria were detected.

x: 10⁸ cells/mL or more of viable bacteria were detected.

The configurations of the polishing compositions of Examples and Comparative Examples are shown in Table 1 below, and the results of the above evaluations are shown in Table 2 below.

TABLE 1

| | Component (A) | | | | | | | | | | | | | | | | | |
|---|---|---|---|---|---|---|---|---|---|---|---|---|---|---|---|---|---|---|
| | | Average | Average | | | | | | | | | | | | | | Polishing | |
| | | primary | secondary | Zeta | | | | | | | | | | | | | composition | |
| | | particle | particle | poten- | | Component (B) | | Component (C) | | | Component (D) | | | Mass | Inorganic salt | | pH | |
| | | size | size | tial | Concentration | | Concentration | | | Concentration | | | Concentration | ratio of | | Concentration | adjusting | |
| | Type | (nm) | (nm) | (mV) | (% by mass) | Type | (% by mass) | Type | Mw | (% by mass) | Type | Mw | (% by mass) | (C)/(D) | Type | (% by mass) | agent | pH |
| Ex. 1 | Abrasive | 34 | 70 | −35 | 4 | BIT | 120 | PVA | 10,000 | 1,000 | PPG2 | 400 | 600 | 1.7 | (NH₄)₂SO₄ | 2,000 | Nitric | 3.0 |
| | grains 1 | | | | | | | | | | | | | | | | acid | |
| Ex. 2 | Abrasive | 34 | 70 | −35 | 4 | BIT | 120 | PA1 | 25,000 | 3,000 | PPG2 | 400 | 500 | 6.0 | (NH₄)₂SO₄ | 2,000 | Nitric | 2.1 |
| | grains 1 | | | | | | | | | | | | | | | | acid | |
| Ex. 3 | Abrasive | 15 | 35 | −15 | 6 | BIT | 120 | PA1 | 25,000 | 3,000 | PPG2 | 400 | 500 | 6.0 | (NH₄)₂HPO₄ | 4,000 | Nitric | 2.1 |
| | grains 2 | | | | | | | | | | | | | | | | acid | |
| Ex. 4 | Abrasive | 15 | 35 | −17 | 6 | BIT | 120 | PA1 | 25,000 | 500 | PPG2 | 400 | 500 | 1.0 | (NH₄)₂HPO₄ | 4,000 | Nitric | 2.1 |
| | grains 2 | | | | | | | | | | | | | | | | acid | |
| Ex. 5 | Abrasive | 15 | 35 | −17 | 6 | BIT | 120 | PA1 | 25,000 | 200 | PPG2 | 400 | 500 | 0.4 | (NH₄)₂HPO₄ | 4,000 | Nitric | 2.1 |
| | grains 2 | | | | | | | | | | | | | | | | acid | |
| Ex. 6 | Abrasive | 15 | 35 | −15 | 6 | BIT | 120 | PA1 | 25,000 | 3,000 | PPG2 | 400 | 1,000 | 3.0 | (NH₄)₂HPO₄ | 4,000 | Nitric | 2.1 |
| | grains 2 | | | | | | | | | | | | | | | | acid | |
| Ex. 7 | Abrasive | 15 | 35 | −15 | 6 | BIT | 120 | PA1 | 25,000 | 3,000 | PPG2 | 400 | 300 | 10.0 | (NH₄)₂HPO₄ | 4,000 | Nitric | 2.1 |
| | grains 2 | | | | | | | | | | | | | | | | acid | |
| Ex. 8 | Abrasive | 15 | 35 | −15 | 6 | BIT | 120 | PA1 | 25,000 | 3,000 | PPG2 | 400 | 100 | 30.0 | (NH₄)₂HPO₄ | 4,000 | Nitric | 2.1 |
| | grains 2 | | | | | | | | | | | | | | | | acid | |
| Ex. 9 | Abrasive | 15 | 35 | −15 | 6 | BIT | 120 | PA2 | 150,000 | 3,000 | PPG2 | 400 | 500 | 6.0 | (NH₄)₂HPO₄ | 4,000 | Nitric | 2.1 |
| | grains 2 | | | | | | | | | | | | | | | | acid | |
| Ex. 10 | Abrasive | 15 | 35 | −15 | 6 | BIT | 120 | PA1 | 25,000 | 3,000 | PPG1 | 200 | 500 | 6.0 | (NH₄)₂HPO₄ | 4,000 | Nitric | 2.1 |
| | grains 2 | | | | | | | | | | | | | | | | acid | |
| Ex. 11 | Abrasive | 15 | 35 | −15 | 6 | BIT | 120 | PA1 | 25,000 | 3,000 | PPG3 | 600 | 500 | 6.0 | (NH₄)₂HPO₄ | 4,000 | Nitric | 2.1 |
| | grains 2 | | | | | | | | | | | | | | | | acid | |
| Ex. 12 | Abrasive | 15 | 35 | −15 | 6 | BIT | 120 | PA1 | 25,000 | 3,000 | PEG | 600 | 500 | 6.0 | (NH₄)₂HPO₄ | 4,000 | Nitric | 2.1 |
| | grains 2 | | | | | | | | | | | | | | | | acid | |
| Ex. 13 | Abrasive | 15 | 35 | −15 | 6 | BIT | 120 | PVA | 10,000 | 3,000 | PPG2 | 400 | 500 | 6.0 | (NH₄)₂HPO₄ | 4,000 | Nitric | 2.1 |
| | grains 2 | | | | | | | | | | | | | | | | acid | |
| Ex. 14 | Abrasive | 34 | 70 | −30 | 2 | BIT | 120 | PA1 | 25,000 | 500 | PEG | 600 | 300 | 1.7 | (NH₄)₂SO₄ | 5,000 | Nitric | 2.2 |
| | grains 1 | | | | | | | | | | | | | | | | acid | |
| Comp. | Abrasive | 15 | 35 | −15 | 6 | — | — | PA1 | 25,000 | 3,000 | PPG2 | 400 | 500 | 6.0 | (NH₄)₂HPO₄ | 4,000 | Nitric | 2.1 |
| Ex. 1 | grains 2 | | | | | | | | | | | | | | | | acid | |
| Comp. | Abrasive | 15 | 35 | −15 | 6 | BIT | 120 | — | — | — | — | — | — | — | (NH₄)₂HPO₄ | 4,000 | Nitric | 2.1 |
| Ex. 2 | grains 2 | | | | | | | | | | | | | | | | acid | |
| Comp. | Abrasive | 15 | 35 | −15 | 6 | BIT | 120 | PA1 | 25,000 | 3,000 | — | — | — | — | (NH₄)₂HPO₄ | 4,000 | Nitric | 2.1 |
| Ex. 3 | grains 2 | | | | | | | | | | | | | | | | acid | |
| Comp. | Abrasive | 15 | 35 | −15 | 6 | BIT | 120 | — | — | — | PPG2 | 400 | — | — | (NH₄)₂HPO₄ | 4,000 | Nitric | 2.1 |
| Ex. 4 | grains 2 | | | | | | | | | | | | | | | | acid | |

TABLE 2

| | Before storage | | | After storage | | |
|---|---|---|---|---|---|---|
| | Polishing removal rate | | | Polishing | Rate of | |
| | | Poly- | | removal | change in | Anti- |
| | TEOS | Si | SiN | rate | polishing | septic |
| | (Å/ | (Å/ | (Å/ | Poly-Si | removal rate | perfor- |
| | min) | min) | min) | (Å/min) | (%) | mance |
| Example 1 | 361 | 675 | 474 | 665 | −1 | ∘ |
| Example 2 | 417 | 629 | 667 | 615 | −2 | ∘ |
| Example 3 | 322 | 301 | 467 | 298 | −1 | ∘ |
| Example 4 | 310 | 421 | 482 | 412 | −2 | ∘ |
| Example 5 | 308 | 381 | 391 | 363 | −5 | ∘ |
| Example 6 | 315 | 291 | 465 | 288 | −1 | ∘ |
| Example 7 | 335 | 385 | 468 | 375 | −3 | ∘ |
| Example 8 | 337 | 401 | 467 | 381 | −5 | ∘ |
| Example 9 | 362 | 475 | 451 | 469 | −1 | ∘ |
| Example 10 | 324 | 332 | 468 | 323 | −3 | ∘ |
| Example 11 | 321 | 290 | 465 | 286 | −1 | ∘ |
| Example 12 | 321 | 305 | 471 | 296 | −3 | ∘ |
| Example 13 | 301 | 255 | 472 | 248 | −3 | ∘ |
| Example 14 | 283 | 496 | 265 | 504 | 2 | ∘ |
| Comparative | 320 | 300 | 463 | 297 | −1 | x |
| Example 1 | | | | | | |
| Comparative | 301 | 189 | 489 | 151 | −20 | ∘ |
| Example 2 | | | | | | |
| Comparative | 324 | 701 | 479 | 635 | −9 | ∘ |
| Example 3 | | | | | | |
| Comparative | 288 | 125 | 462 | 109 | −13 | ∘ |
| Example 4 | | | | | | |

As is clear from Table 2 above, it was found that the polishing compositions of Examples have excellent storage stability, showing less change in polishing removal rate compared to the polishing compositions of Comparative Examples even after long-term storage, being capable of stably maintaining polishing performance, and being capable of suppressing proliferation of viable bacteria.

1. A polishing composition comprising:
(A) abrasive grains;
(B) a biocide;
(C) a polishing removal rate improver for a material having a silicon-silicon bond; and
(D) a polyoxyalkylene compound,
wherein the component (B) is at least one selected from the group consisting of an isothiazolinone compound and a thiazolinone compound, and
wherein the component (C) is a water-soluble polymer other than the component (D).

2. The polishing composition according to claim 1, wherein the component (C) is at least one selected from the group consisting of an anionic water-soluble polymer and a nonionic water-soluble polymer other than the component (D).

3. The polishing composition according to claim 1, wherein the component (C) is at least one selected from the group consisting of polycarboxylic acid, polycarboxylic acid amide, polycarboxylic acid ester, polycarboxylic acid salt, polysulfonic acid, polyphosphonic acid, and vinyl-based polymer.

4. The polishing composition according to claim 1, wherein the component (C) is polyacrylic acid or polyvinyl alcohol.

5. The polishing composition according to claim 1, wherein a concentration of the component (C) with respect to a total mass of the polishing composition is 500 ppm by mass or more.

6. The polishing composition according to claim 1, wherein the component (D) is a compound represented by the following formula (1): 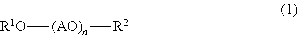
wherein
R¹ and R² are each independently a hydrogen atom or an alkyl group having 1 or more and 10 or less carbon atoms;
AO is an oxyalkylene group having 2 or more and 4 or less carbon atoms; and
n represents an average number of added moles of the oxyalkylene group and is a number of 2 or more and 20 or less.

7. The polishing composition according to claim 1, wherein the component (D) is polyethylene glycol or polypropylene glycol.

8. The polishing composition according to claim 1, wherein a concentration of the component (D) with respect to a total mass of the polishing composition is 200 ppm by mass or more.

9. The polishing composition according to claim 1, wherein a content mass ratio of the component (C) to the component (D) (component (C)/component (D)) is 0.1 or more and 10 or less.

10. The polishing composition according to claim 1, wherein the abrasive grains are sulfonic acid-modified colloidal silica.

11. The polishing composition according to claim 1, further comprising a dispersing medium.

12. The polishing composition according to claim 1, wherein pH of the polishing composition is 1 or more and 5 or less.

13. The polishing composition according to claim 1, wherein pH of the polishing composition is 1.5 or more and 3 or less.

14. The polishing composition according to claim 1, used for polishing an object to be polished including a material having a silicon-silicon bond.

15. The polishing composition according to claim 14, wherein the object to be polished further comprises at least one selected from a material having a silicon-oxygen bond and a material having a silicon-nitrogen bond.

16. A polishing method comprising polishing an object to be polished including a material having a silicon-silicon bond, using the polishing composition set forth in claim 1.
